(19) United States
(12) Patent Application Publication
(10) Pub. No.: US 2026/0287635 A1
(43) Pub. Date: Sep. 24, 2026

(54) DETERIORATION DIAGNOSIS METHOD AND DETERIORATION DIAGNOSIS DEVICE, FOR VARISTOR

(71) Applicant: KYOCERA Document Solutions Inc., Osaka (JP)

(72) Inventor: Shaoyang WANG, Osaka (JP)

(73) Assignee: KYOCERA Document Solutions Inc., Osaka (JP)

(21) Appl. No.: 19/567,582

(22) Filed: Mar. 16, 2026

(30) Foreign Application Priority Data
Mar. 24, 2025 (JP) 2025-048968

(51) Int. Cl. G01R 31/12; H02H 9/04

(52) U.S. Cl. CPC G01R 31/1236; H02H 9/042

(57) ABSTRACT

Provided is a varistor deterioration diagnosis method, for diagnosing deterioration of the varistor, provided in an electronic device including a protected circuit to be protected from a surge, and the varistor connected to a power line between a commercial power source that supplies an AC voltage and the protected circuit. The method includes applying a predetermined surge voltage to the varistor provided in the electronic device, measuring a breakdown voltage of the varistor, and deciding that the varistor is unusable, when the measured breakdown voltage exceeds a predetermined deterioration threshold, and deciding that the varistor is usable, when the measured breakdown voltage is equal to or lower than the predetermined deterioration threshold.

### INCORPORATION BY REFERENCE

This application claims priority to Japanese Patent Application No.2025-048968 filed on Mar. 24, 2025, the entire contents of which are incorporated by reference herein.

### BACKGROUND

The present disclosure relates to a deterioration diagnosis method and a deterioration diagnosis device, for a voltage-dependent resistor, generally known as a varistor.

The varistor refers to an electronic part having two electrodes, and having a characteristic that the resistance varies depending on the voltage between the two terminals. The varistor is used for the purpose of protecting an electric circuit from a surge voltage. The varistor is, for example, connected to a power line between a protected circuit of the electric circuit and a commercial power source. When the surge voltage is applied to the power line, the varistor absorbs the surge voltage, thereby preventing the protected circuit from being subjected to an abnormally high voltage.

### SUMMARY

The disclosure proposes further improvement of the foregoing techniques.

In an aspect, the disclosure provides a varistor deterioration diagnosis method, for diagnosing deterioration of the varistor, provided in an electronic device including a protected circuit to be protected from a surge, and the varistor connected to a power line between a commercial power source that supplies an AC voltage and the protected circuit. The deterioration diagnosis method includes applying a predetermined surge voltage to the varistor provided in the electronic device, measuring a breakdown voltage of the varistor, and deciding that the varistor is unusable, when the measured breakdown voltage exceeds a predetermined deterioration threshold, and deciding that the varistor is usable, when the measured breakdown voltage is equal to or lower than the predetermined deterioration threshold.

In another aspect, the disclosure provides a varistor deterioration diagnosis device that diagnoses deterioration of the varistor, provided in an electronic device including a protected circuit to be protected from a surge, the varistor connected to a power line between a commercial power source that supplies an AC voltage and the protected circuit, and a power input terminal connected to the commercial power source. The varistor deterioration diagnosis device includes a surge voltage generation device, a power output terminal, a voltage measurement device, a display device, and a controller. The surge voltage generation device generates a predetermined surge voltage, from an AC voltage of the commercial power source. The power output terminal is connected to the power input terminal of the electronic device, and supplies the surge voltage to the electronic device. The voltage measurement device measures a breakdown voltage of the varistor, applied to the power output terminal. The controller causes the display device to display the breakdown voltage measured by the voltage measurement device.

### BRIEF DESCRIPTION OF THE DRAWINGS

FIG. 1 is a schematic diagram showing an example of the configuration and application of a deterioration diagnosis device, according to an embodiment of the disclosure;

FIG. 2 is a functional block diagram schematically showing an essential internal configuration of the deterioration diagnosis device;

FIG. 3 is a graph showing an example of a measurement result, provided by a voltage measurement device through a surge test;

FIG. 4 is a table showing an example of a sample used for the surge test;

FIG. 5A1 to FIG. 5A3 include graphs showing measurement results obtained through the surge test, with respect to a sample 1;

FIG. 5B1 to FIG. 5B3 include graphs showing measurement results obtained through the surge test, with respect to a sample 2;

FIG. 6A1 to FIG. 6A3 include graphs showing measurement results obtained through the surge test, with respect to a sample 3;

FIG. 6B1 to FIG. 6B3 include graphs showing measurement results obtained through the surge test, with respect to a sample 4;

FIG. 7A1 to FIG. 7A3 include graphs showing measurement results obtained through the surge test, with respect to a sample 5;

FIG. 7B1 to FIG. 7B3 include graphs showing measurement results obtained through the surge test, with respect to a sample 6;

FIG. 8A and FIG. 8B are a table and a graph, respectively, showing breakdown voltages, according to the measurement results obtained through the surge test;

FIG. 9A1 to FIG. 9A3 include graphs showing measurement results obtained through the surge test, with respect to a sample 1;

FIG. 9B1 to FIG. 9B3 include graphs showing measurement results obtained through the surge test, with respect to a sample 2;

FIG. 10A1 to FIG. 10A3 include graphs showing measurement results obtained through the surge test, with respect to a sample 3;

FIG. 10B1 to FIG. 10B3 include graphs showing measurement results obtained through the surge test, with respect to a sample 4;

FIG. 11A1 to FIG. 11A3 include graphs showing measurement results obtained through the surge test, with respect to a sample 5;

FIG. 11B1 to FIG. 11B3 include graphs showing measurement results obtained through the surge test, with respect to a sample 6;

FIG. 12A and FIG. 12B are a table and a graph, respectively, showing the breakdown voltages, according to the measurement results obtained through the surge test; and

FIG. 13 is a flowchart showing a deterioration diagnosis method, for diagnosing whether a varistor in an electronic device is usable.

### DETAILED DESCRIPTION

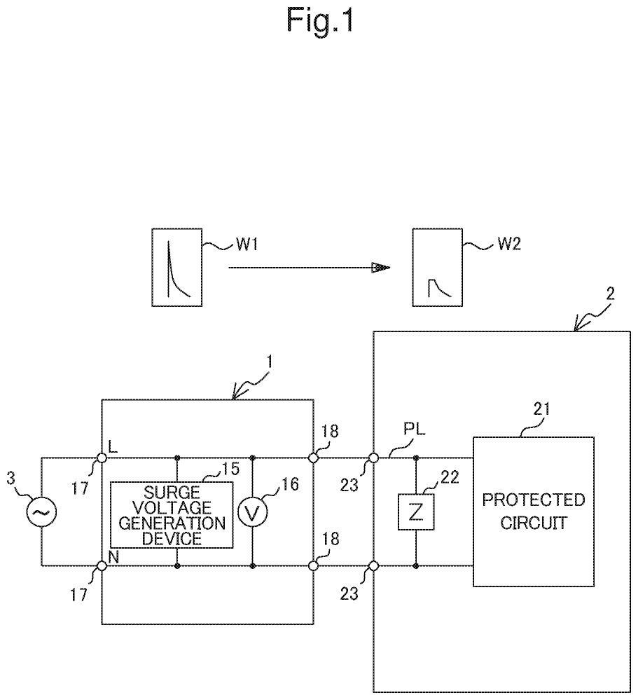

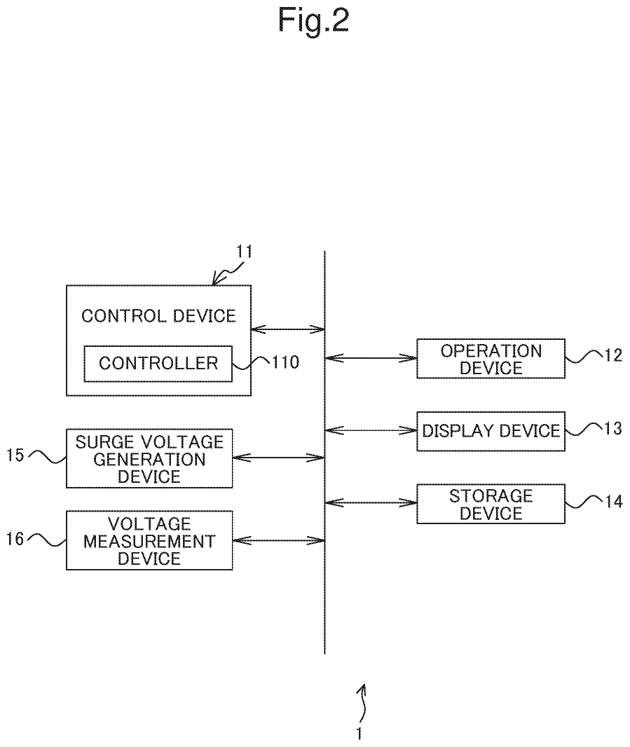

Hereafter, a varistor deterioration diagnosis method and a varistor deterioration diagnosis device according to an embodiment of the disclosure will be described, with reference to the drawings. FIG. 1 is a schematic diagram showing an example of the configuration and application of the deterioration diagnosis device, according to the embodiment of the disclosure. FIG. 2 is a functional block diagram schematically showing an essential internal configuration of the deterioration diagnosis device.

The deterioration diagnosis device 1 is for diagnosing the deterioration of a varistor 22 provided in an electronic device 2. The electronic device 2 includes a protected circuit 21 to be protected from a surge, the varistor 22 connected to a power line PL between a commercial power source 3 that supplies an AC voltage, and the protected circuit 21, and a power input terminal 23 connected to the commercial power source 3. Thus, the protected circuit 21 is connected to the commercial power source 3, via the power input terminal 23.

As shown in FIG. 2, the deterioration diagnosis device 1 includes a control device 11, an operation device 12, a display device 13, a storage device 14, a surge voltage generation device 15, and a voltage measurement device 16. These components are configured to transmit and receive data or signals to and from each other, via a communication bus.

The deterioration diagnosis device 1 also includes, as shown in FIG. 1, power input terminals 17 connected to the commercial power source 3, and a power output terminal 18 that can be connected to the power input terminal 23 of the electronic device 2, to supply the AC voltage of the commercial power source 3, to the electronic device 2. One of the power input terminals 17 is an ungrounded live (L) terminal, and the other is a grounded neutral (N) terminal.

The operation device 12 includes operating keys or a numeric keypad, and receives instructions from the user (operator), inputted by operating the keys. The display device 13 includes, for example, a liquid crystal display (LCD), and displays responses or data results from the control device 11. The storage device 14 is a large-capacity memory unit such as a hard disk drive (HDD) or a solid-state drive (SSD), and contains various control programs.

The surge voltage generation device 15 includes, for example, a voltage amplifier, and generates a predetermined surge voltage to be applied to the power output terminal 18. The surge voltage generation device 15 superimposes a predetermined voltage on the AC voltage of the commercial power source 3, thereby generating the surge voltage.

The varistor 22 is a non-linear element having an electrical characteristic that the resistance is lowered with a voltage exceeding a certain level, so that a current flows. When the varistor 22 in the electronic device 2 properly works, although the surge voltage generation device 15 generates the surge voltage of a waveform W1 (see FIG. 1) and applies such voltage to the protected circuit 21, the varistor 22 suppresses the voltage applied to the protected circuit 21 to a magnitude indicated by a waveform W2 (see FIG. 1).

The surge voltage generation device 15 also generates a plurality of types of surge voltage, which are different from each other, according to the instruction from the operator inputted through the operation device 12. For example, the surge voltage generation device 15 generates the surge voltages, the highest voltages of which are 1 kV, 1.5 kV, 2 kV, and 2.5 kV. The phase for synchronizing the predetermined voltage (different depending on the surge voltage to be generated) with the AC voltage, when generating the surge voltage, can also be selected according to the instruction from the operator inputted through the operation device 12, for example from the phases of 0°, 90°, and 270°.

The voltage measurement device 16 includes, for example, a voltage detector, and measures the voltage applied to the power output terminal 18. When the power output terminal 18 is connected to the power input terminal 23 of the electronic device 2, the voltage measurement device 16 measures the voltage applied to the varistor 22.

The control device 11 includes a processor, a random-access memory (RAM), a read-only memory (ROM), and an exclusive hardware circuit. The processor is, for example, a central processing unit (CPU), an application specific integrated circuit (ASIC), or a micro processing unit (MPU). The control device 11 includes a controller 110.

To be more specific, the control device 11 acts as the controller 110, when the processor operates according to the control program stored in the storage device 14. Here, the controller 110 may be constituted in the form of a hardware circuit, instead of being realized by the operation of the control device 11 according to the control program. This also applies to other embodiments, unless otherwise specifically noted.

The controller 110 serves to control the overall operation of the deterioration diagnosis device 1. The controller 110 is connected to the operation device 12, the display device 13, the storage device 14, the surge voltage generation device 15, and the voltage measurement device 16, and controls the operation of the mentioned components. For example, the controller 110 displays the measurement result provided by the voltage measurement device 16, on the display device 13.

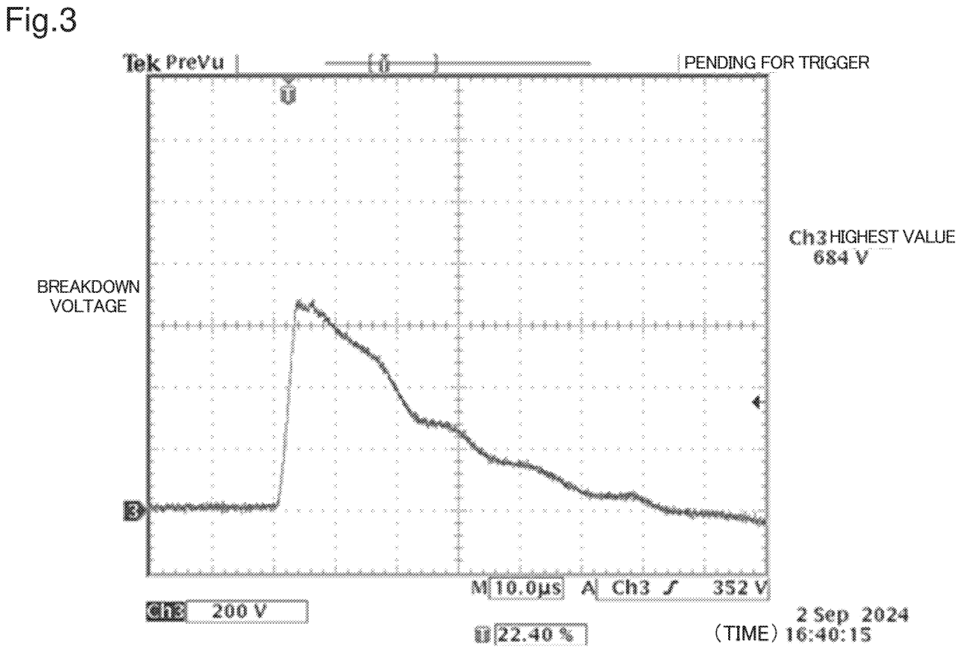

FIG. 3 is a graph showing an example of a measurement result (experiment waveform) displayed on the display device 13, obtained by the voltage measurement device 16 when the surge test is executed by causing the surge voltage generation device 15 to generate the surge voltage. The experiment waveform shown in FIG. 3 indicates the voltage applied to the varistor 22, and the peak value (684V) of the voltage corresponds to the breakdown voltage of the varistor 22. The breakdown voltage refers to the voltage at which the resistance of the varistor 22 sharply drops, so that the current running in the varistor 22 sharply increases. Accordingly, the breakdown voltage of the varistor 22, measured when the surge voltage is applied to the electronic device 2, can be visually recognized, in view of the graph displayed on the display device 13.

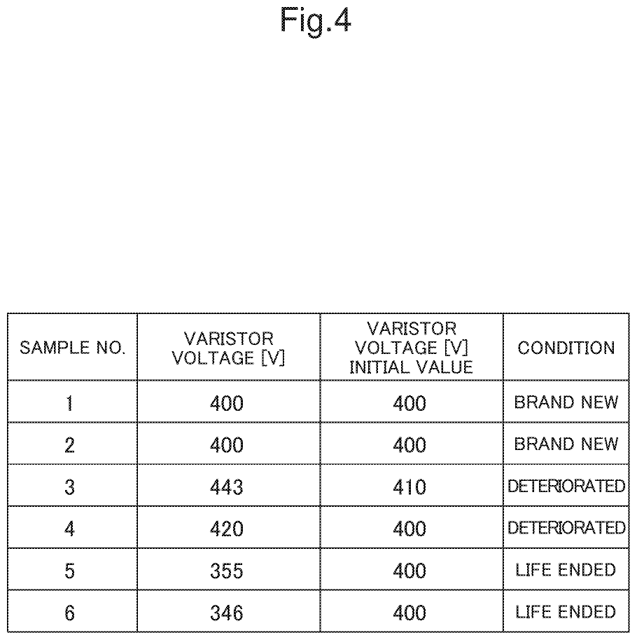

As samples to be used for the surge test for measuring the breakdown voltage, six types of varistors 22 were prepared, as shown in FIG. 4. The samples 1 and 2 are undeteriorated, brand new varistors. Since these are brand new, the varistor voltage is naturally the same as the initial value.

Normally, when the varistor 22 is deteriorated, the varistor voltage varies. The varistor voltages of the samples 3 to 6 are different from the initial value, and therefore these samples are decided to be deteriorated. In the case of the samples 5 and 6, in particular, the varistor voltage is lower than the initial value by more than 10%, and therefore it is decided that the service life of these samples has ended.

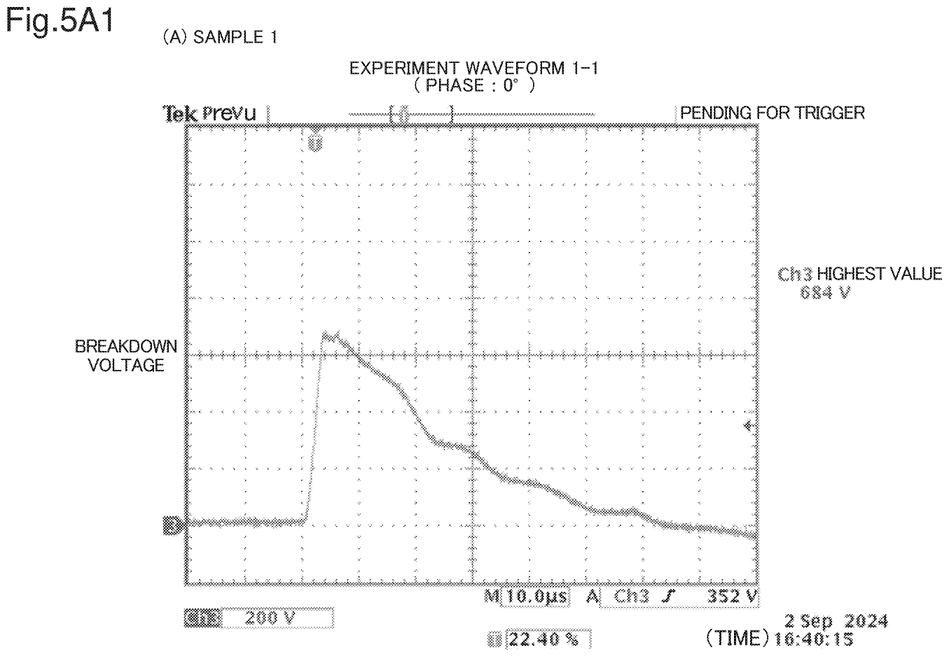

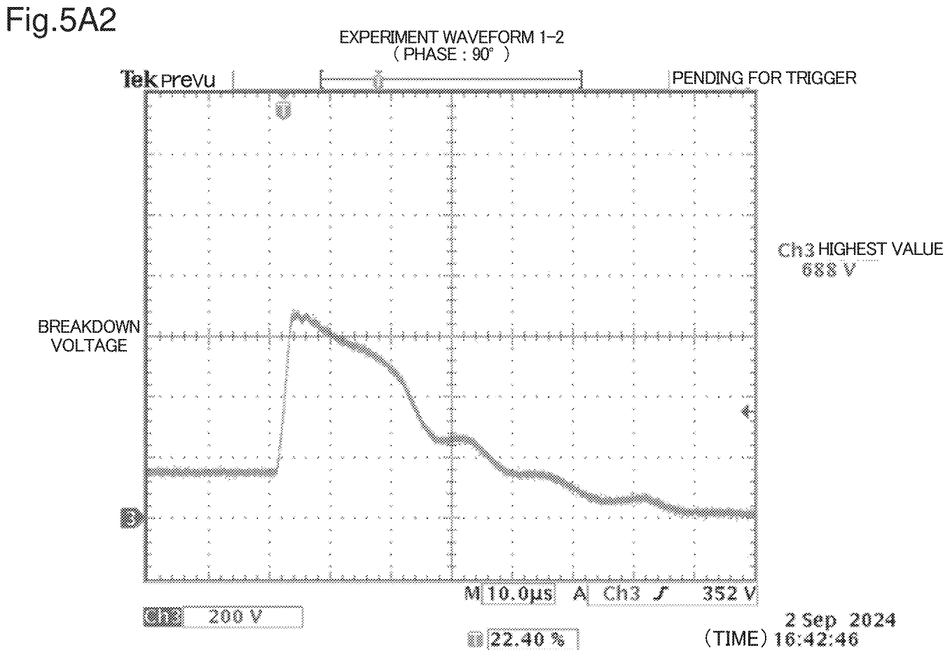

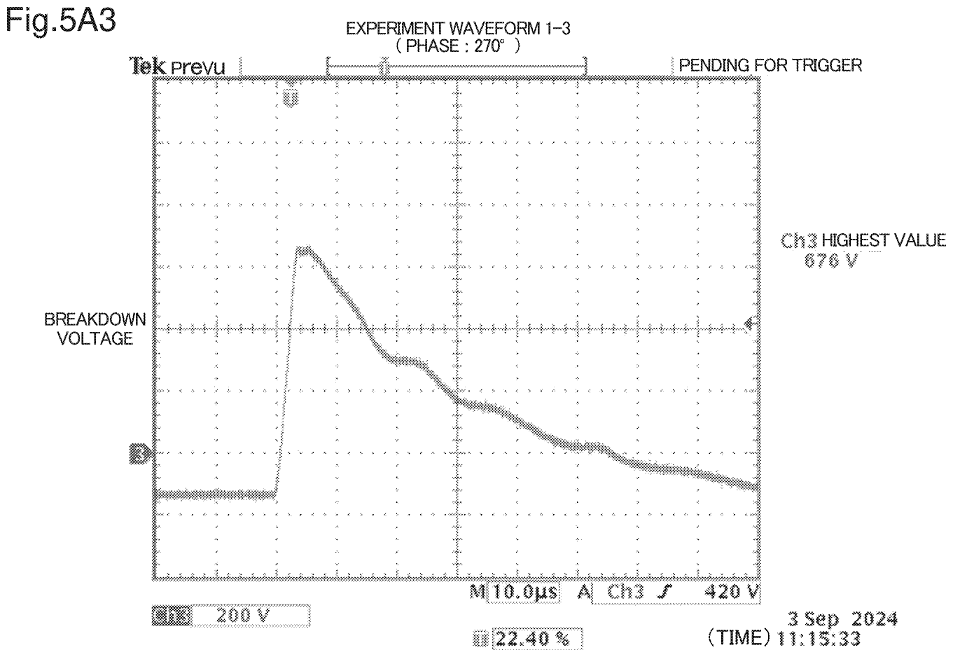

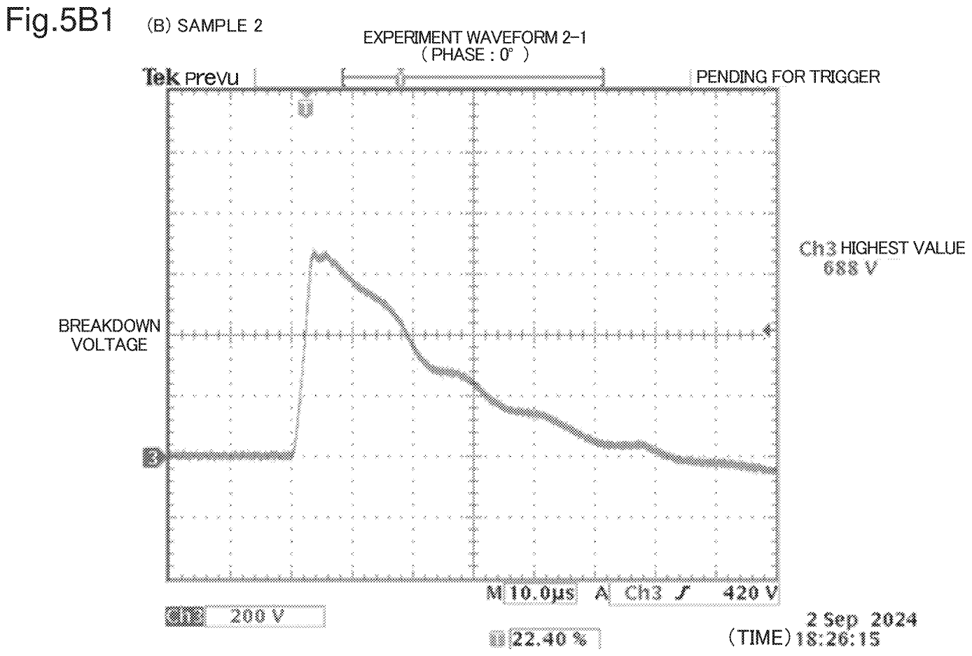

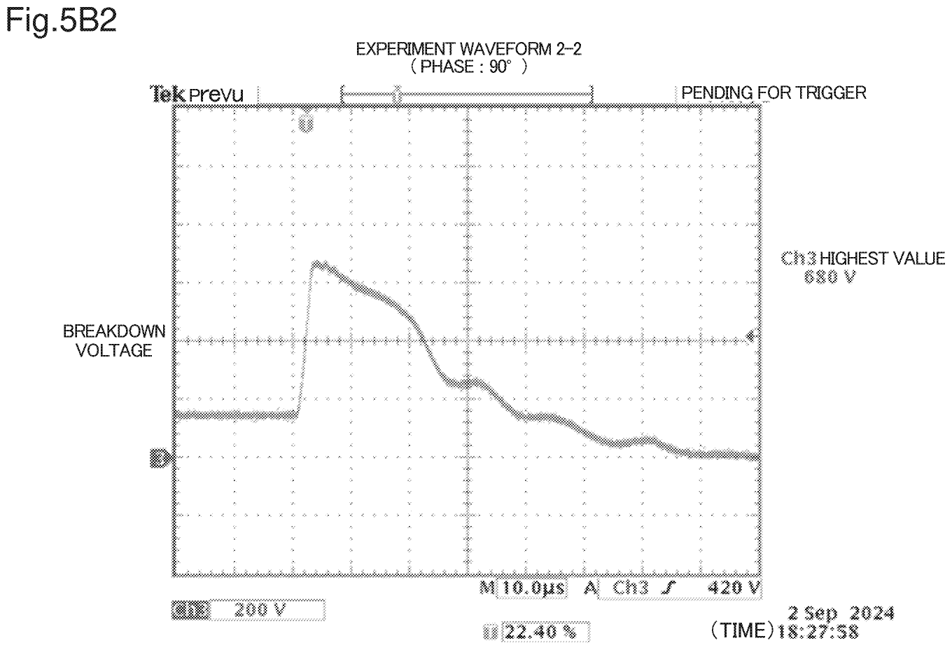

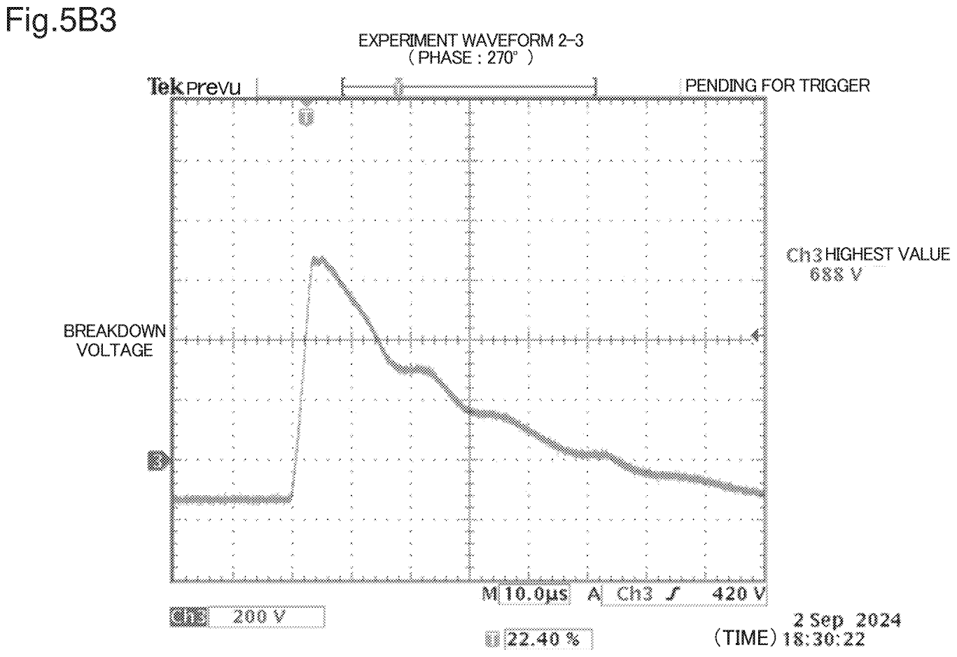

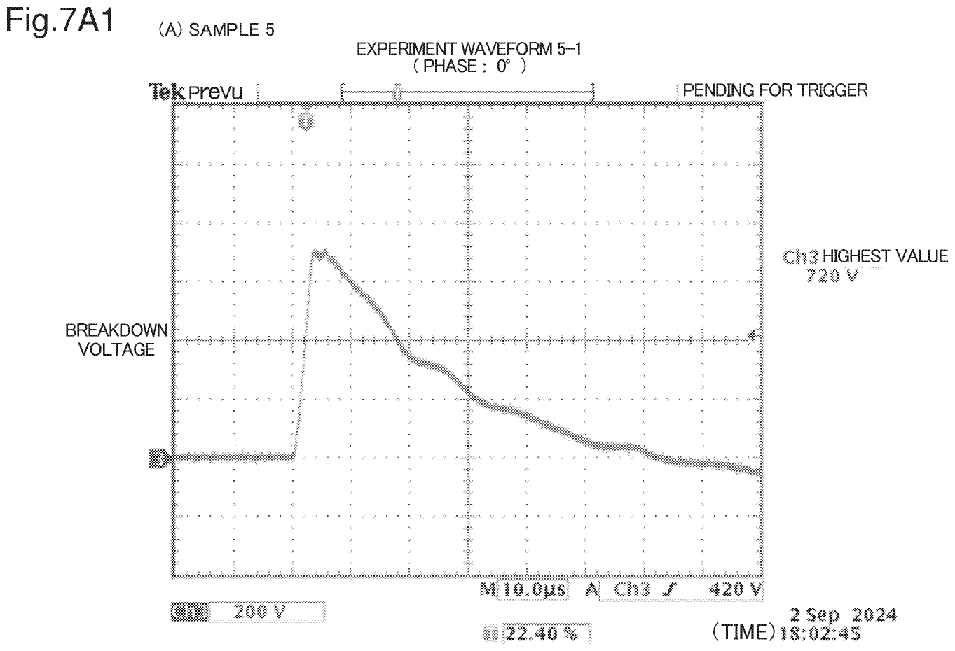

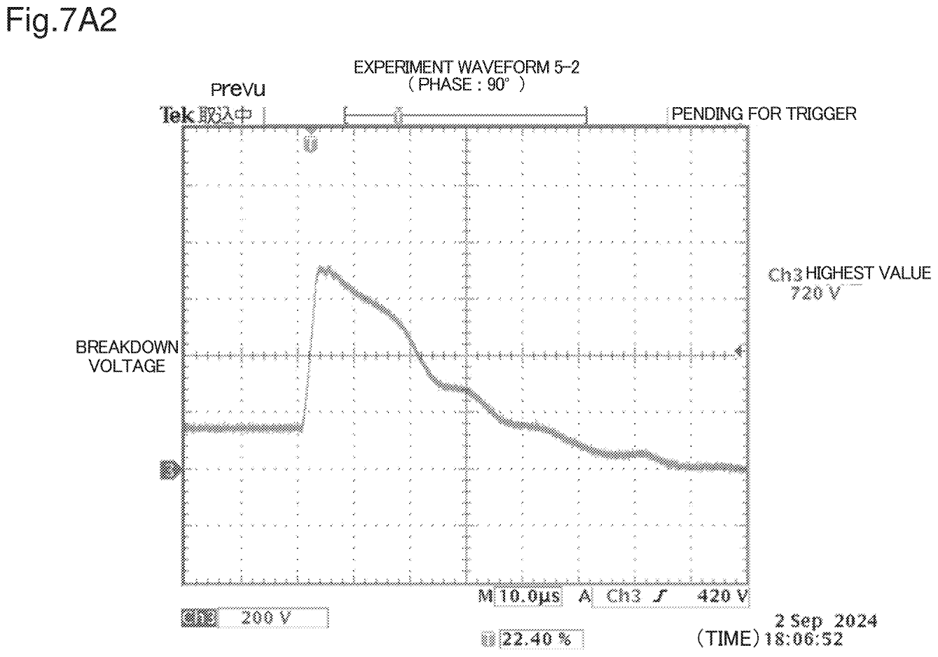

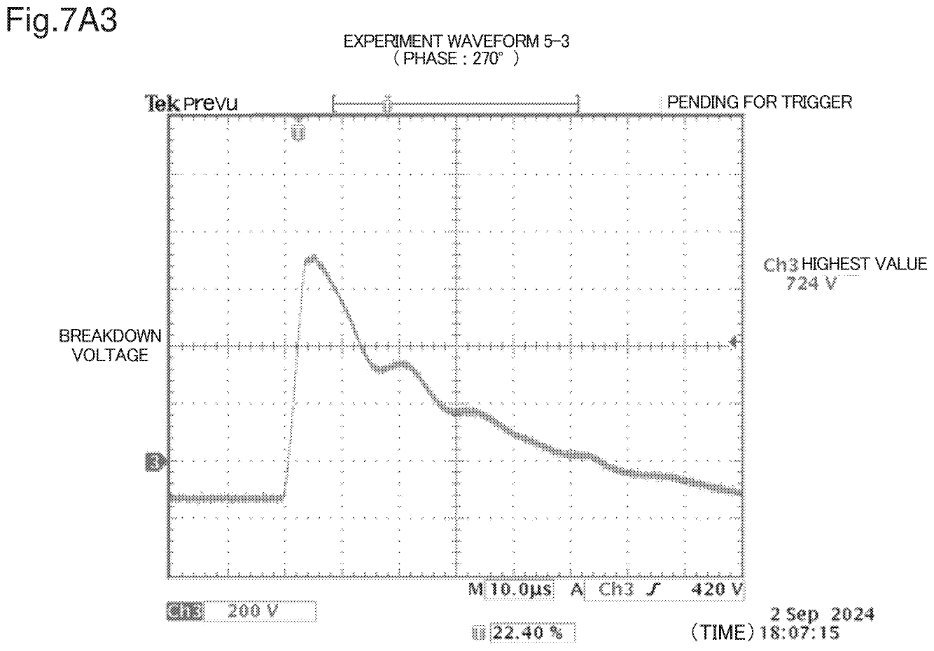

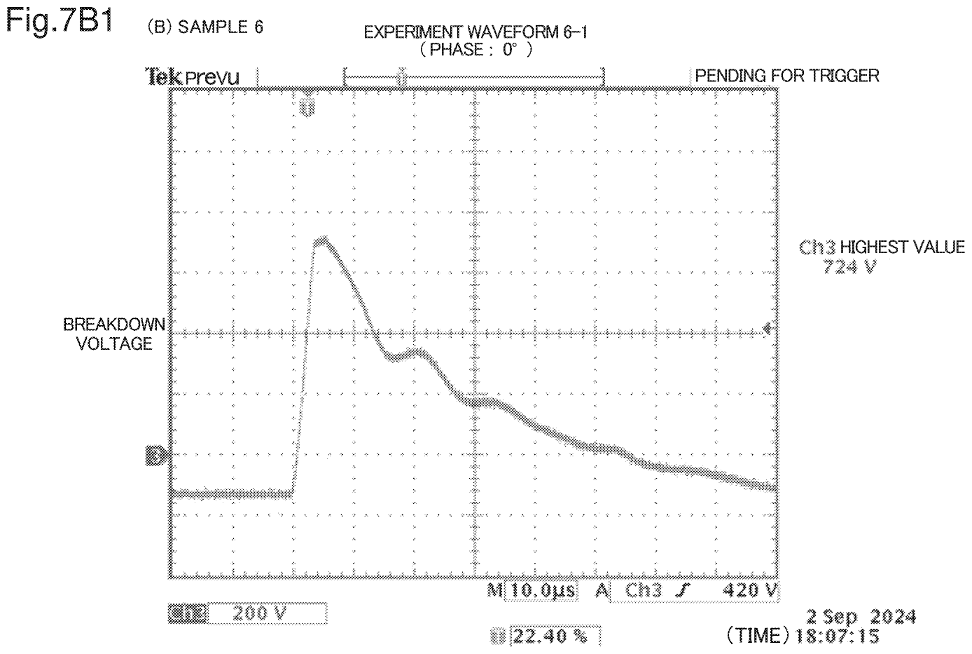

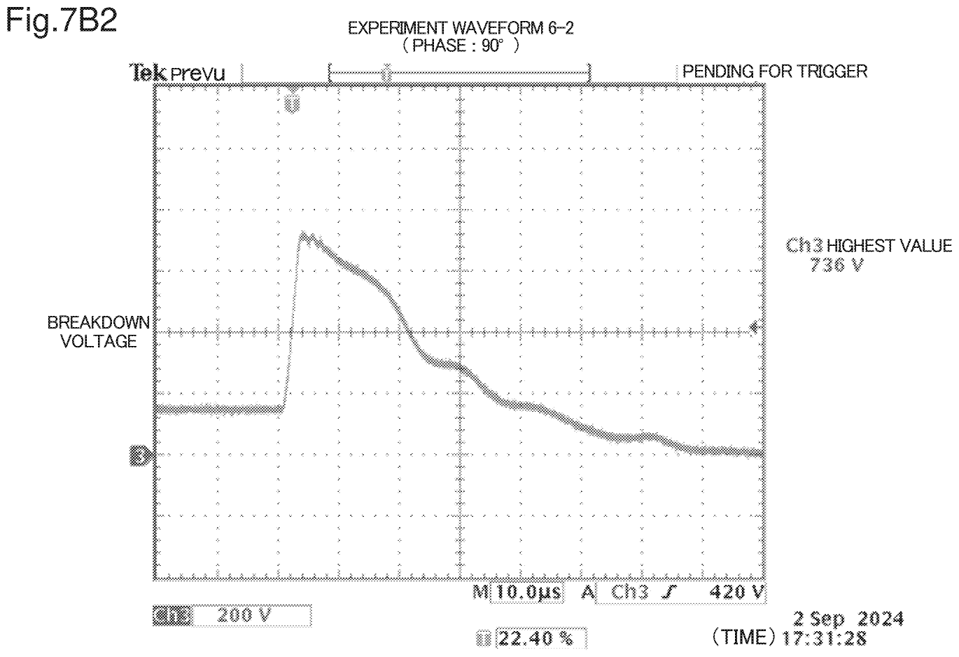

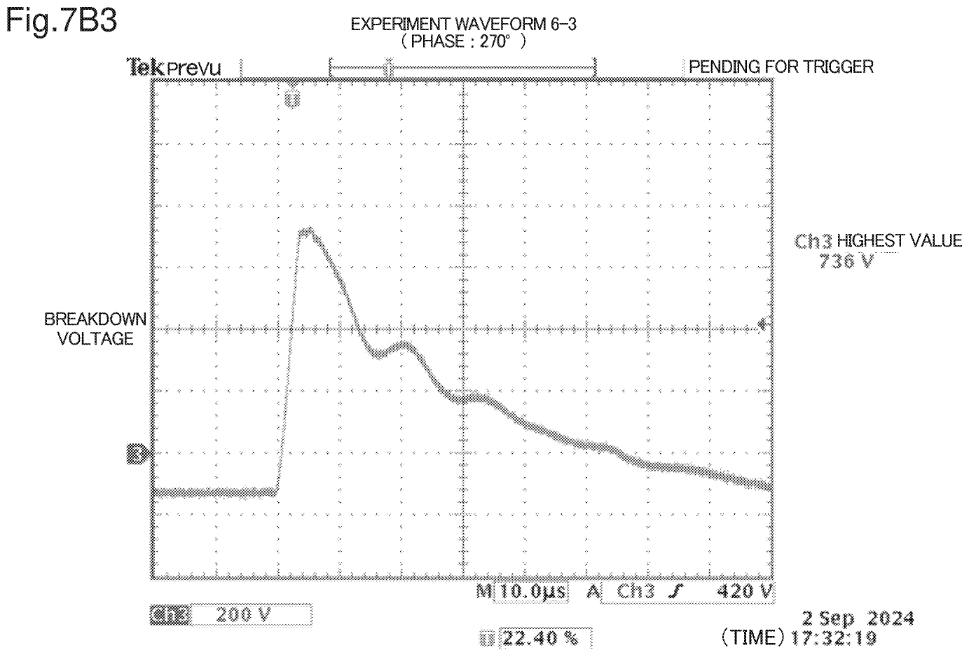

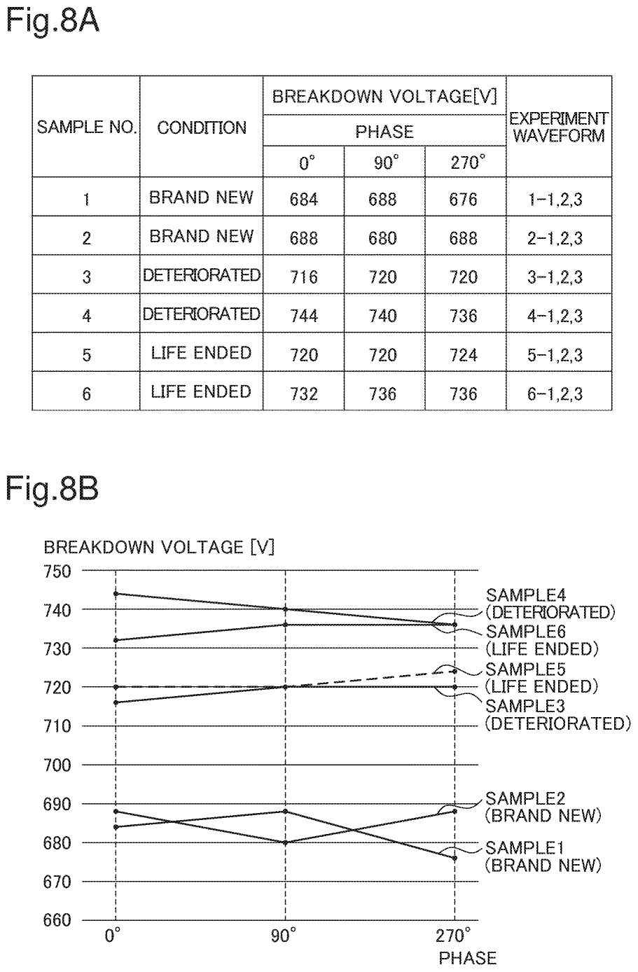

FIG. 5A1 to FIG. 7B3 each includes a graph showing the measurement result of the breakdown voltage, obtained through the surge test executed with the surge voltage of maximum 1 kV (phase: 0°, 90°, and 270°), with respect to the samples 1 to 6. FIG. 8A and FIG. 8B indicate the breakdown voltages, according to the measurement results.

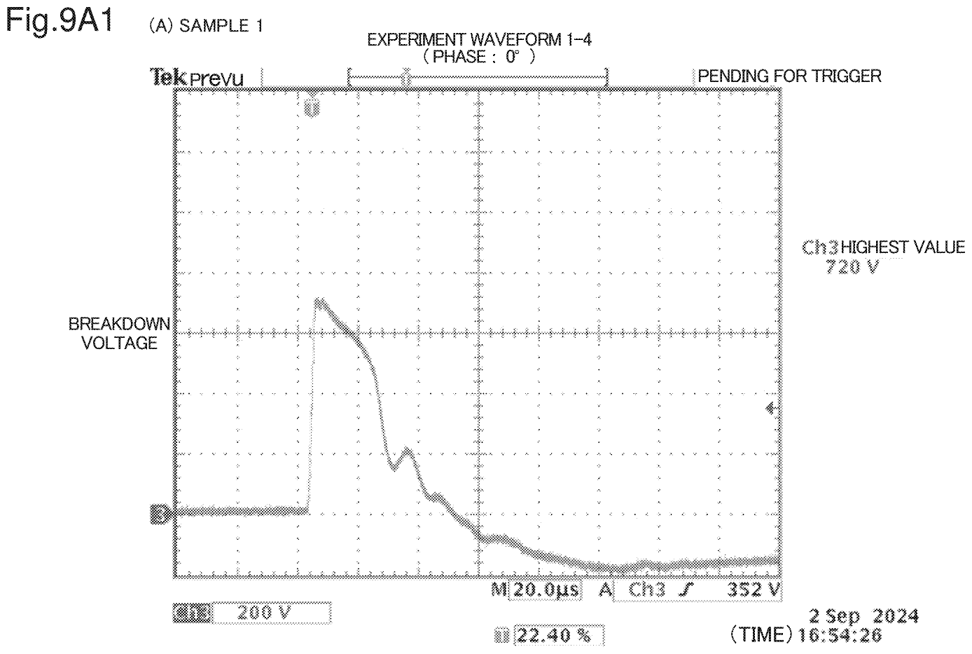

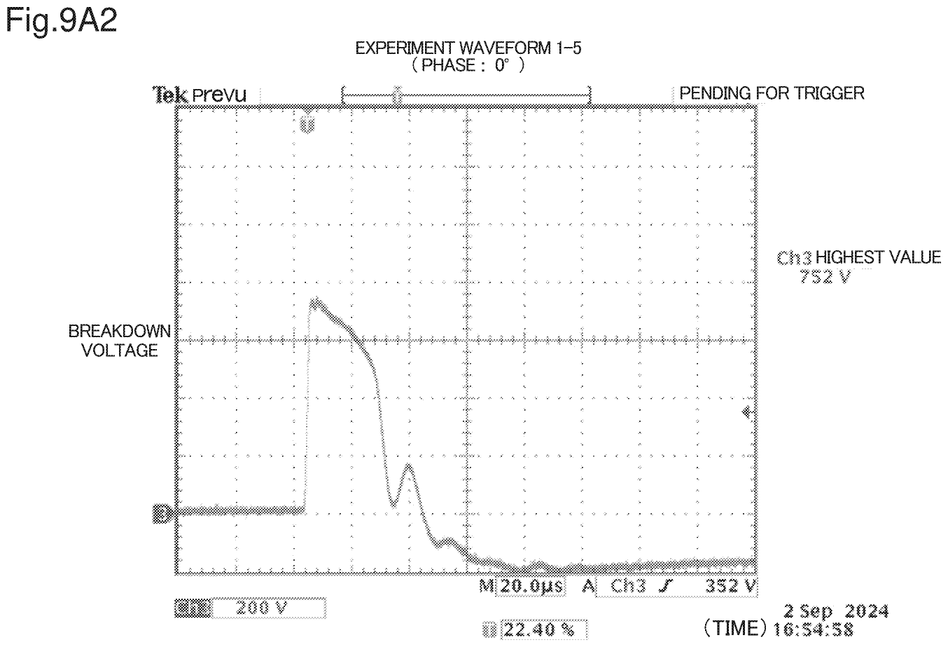

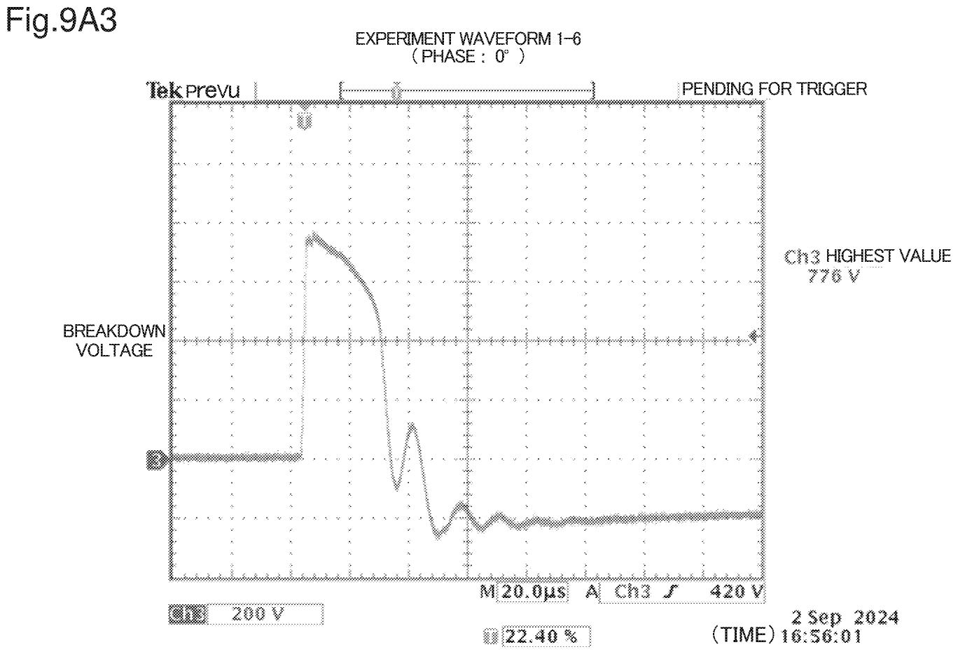

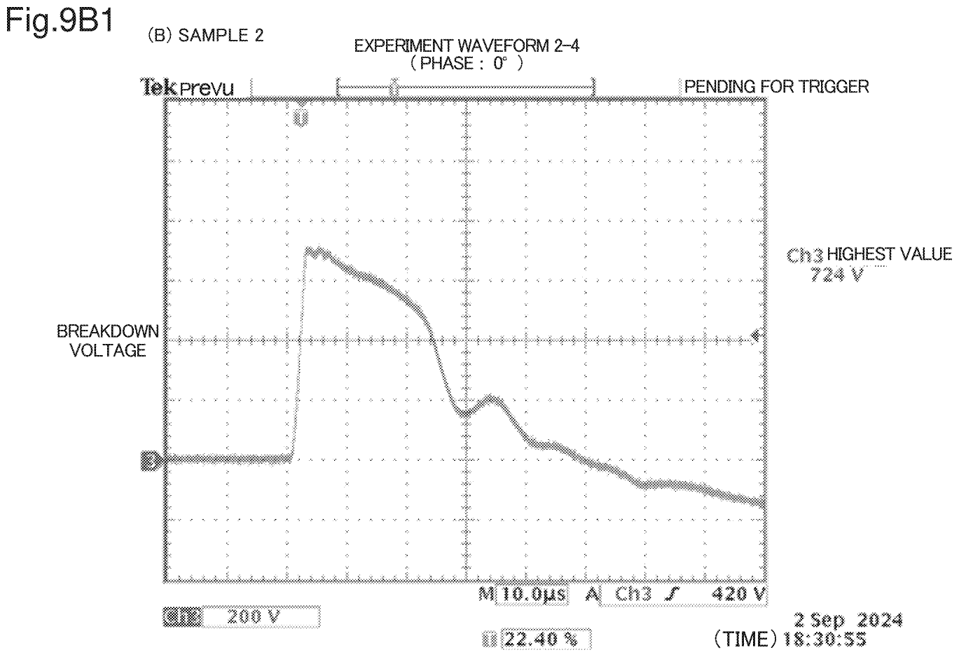

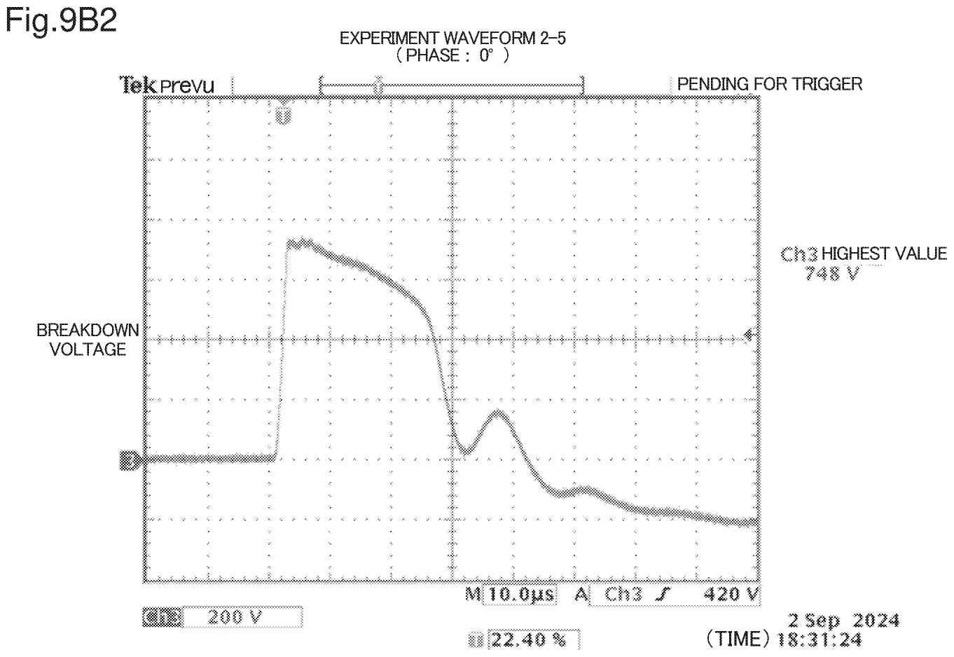

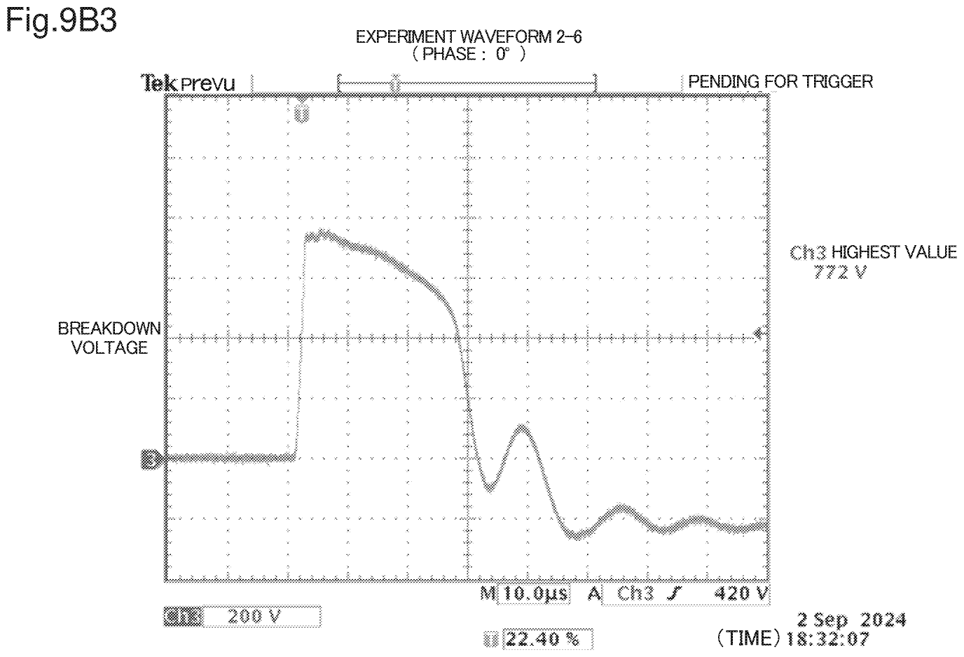

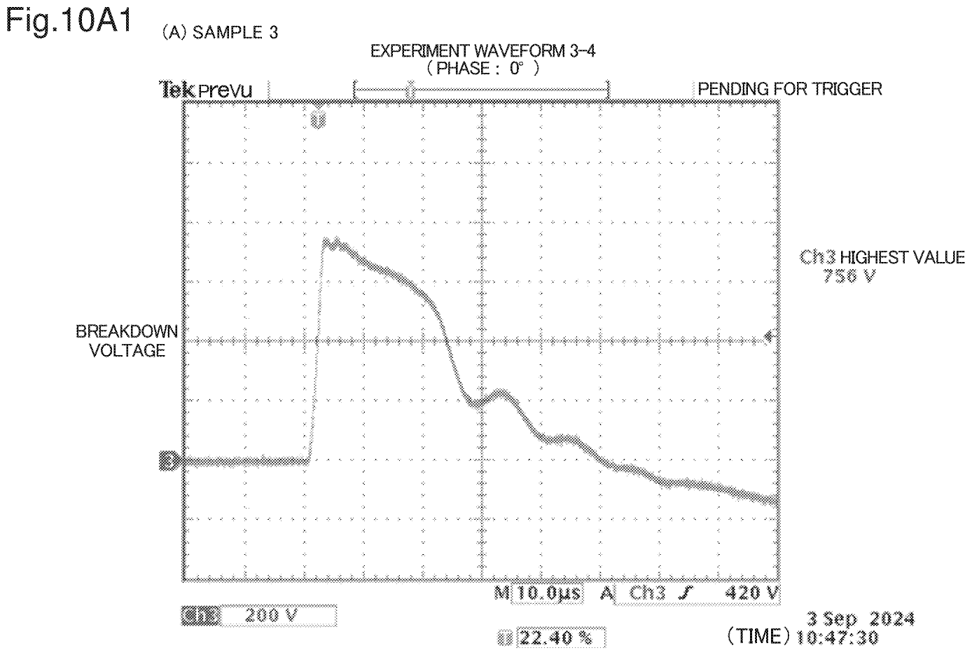

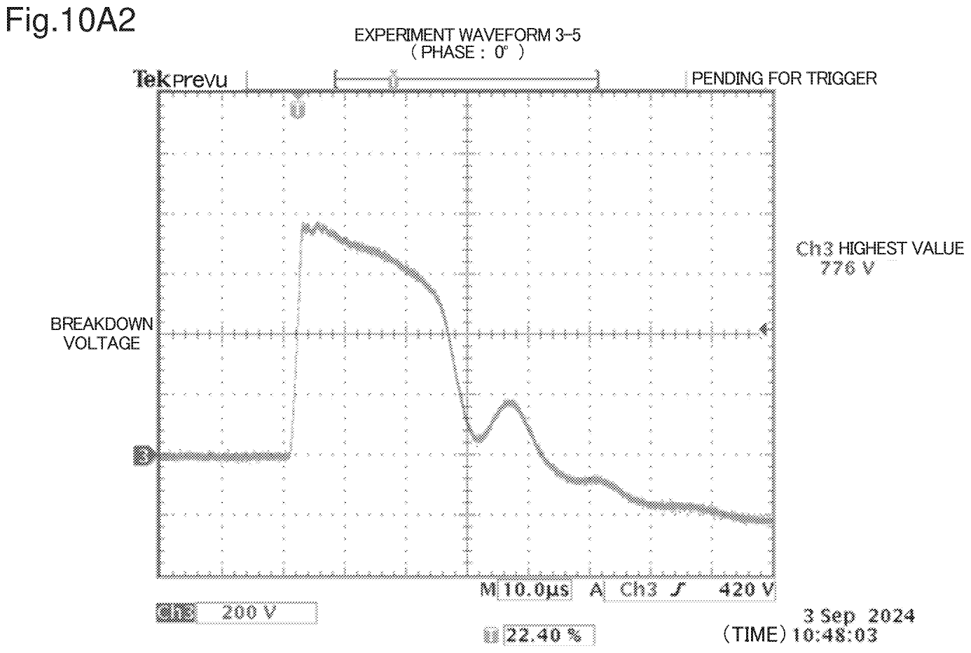

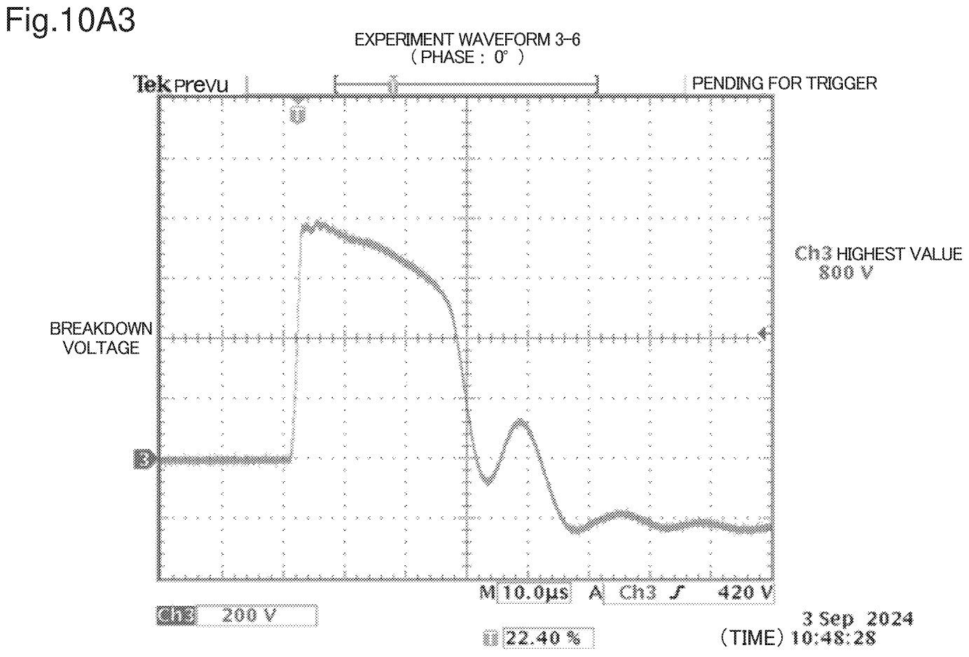

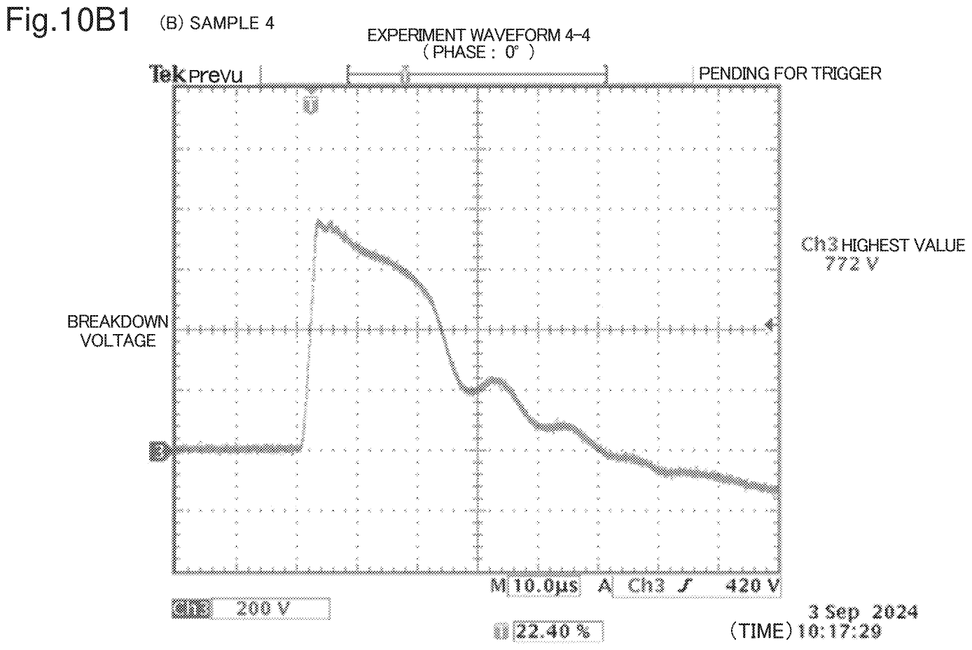

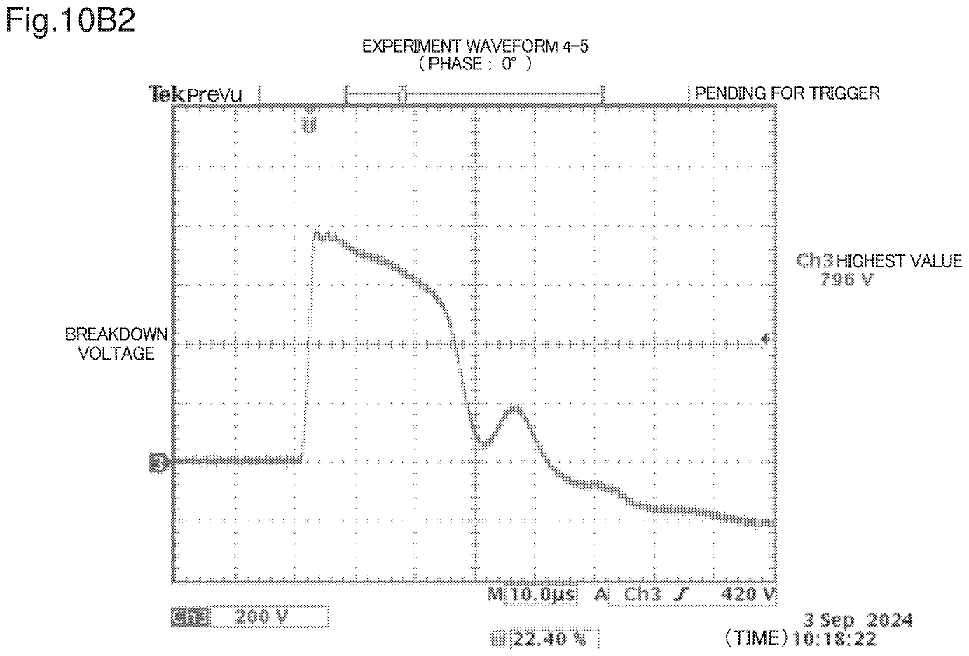

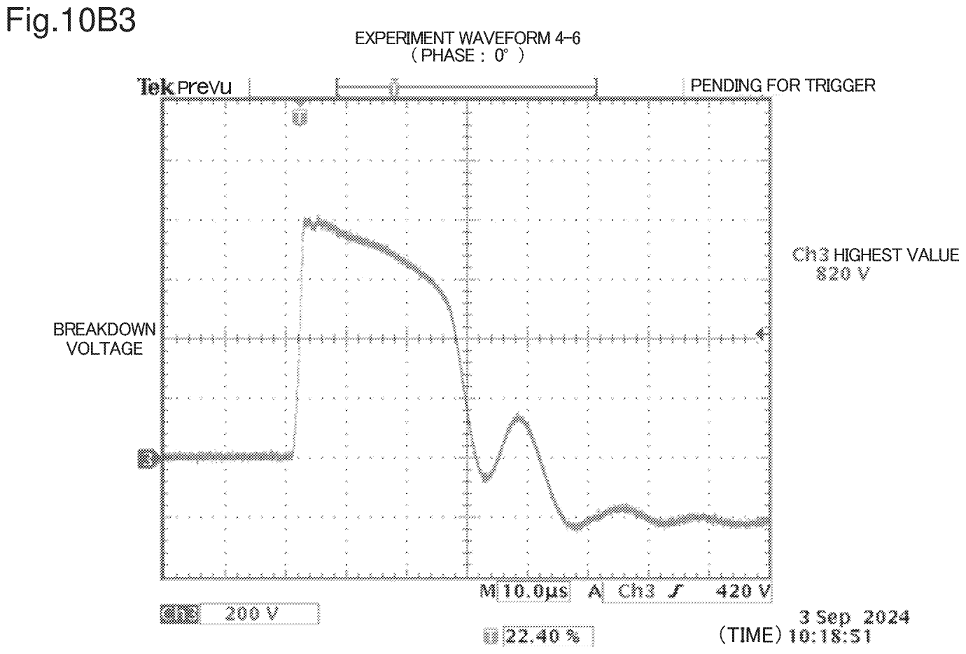

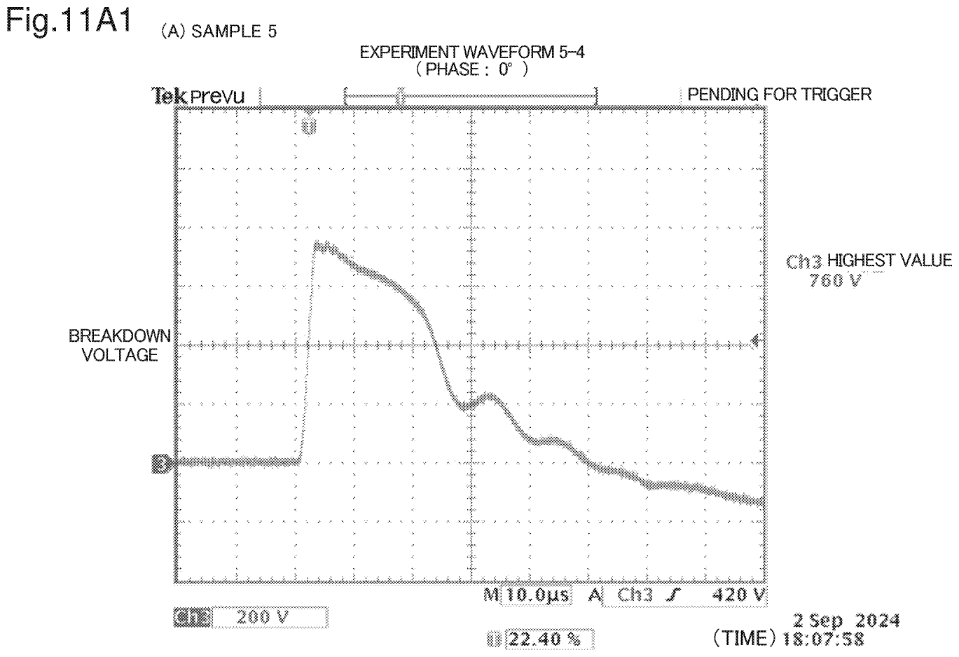

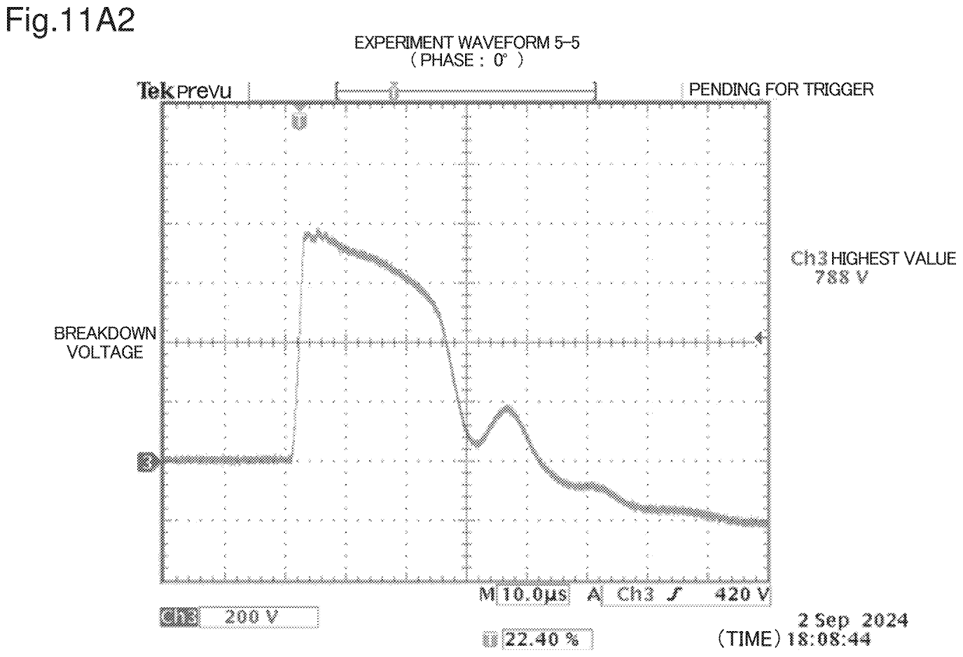

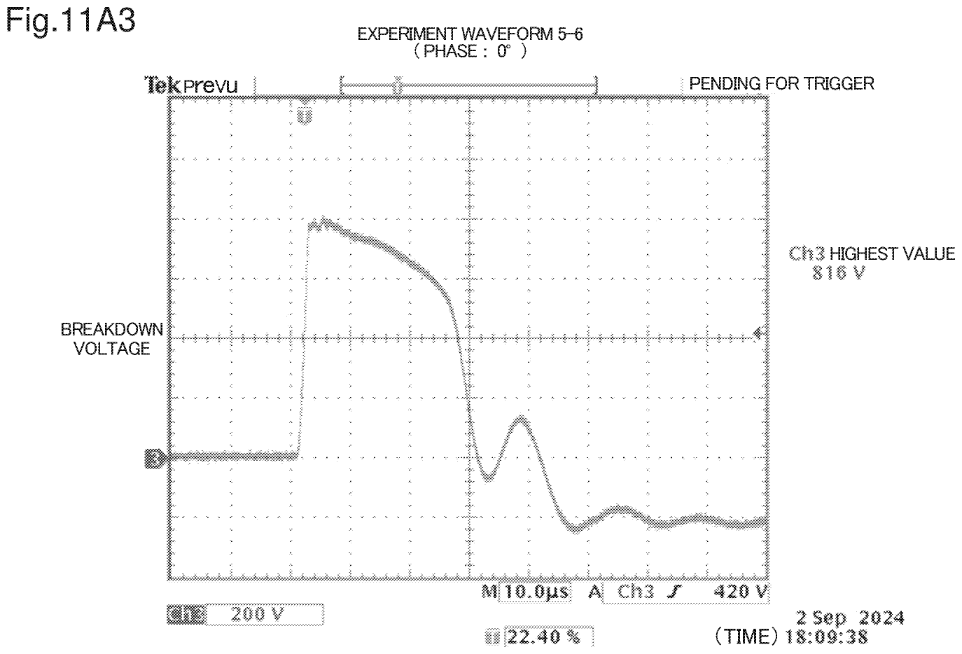

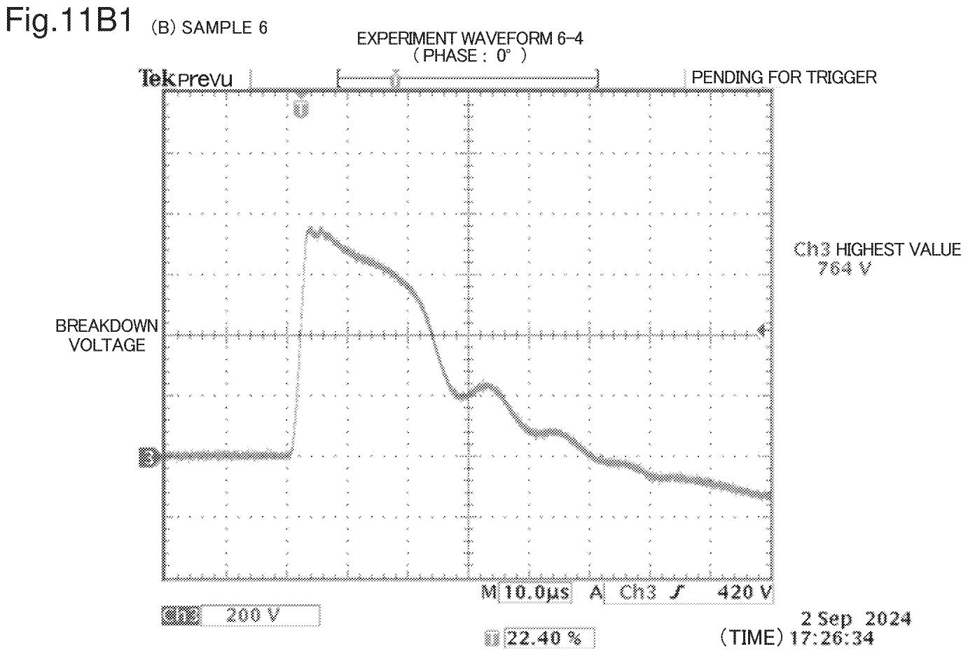

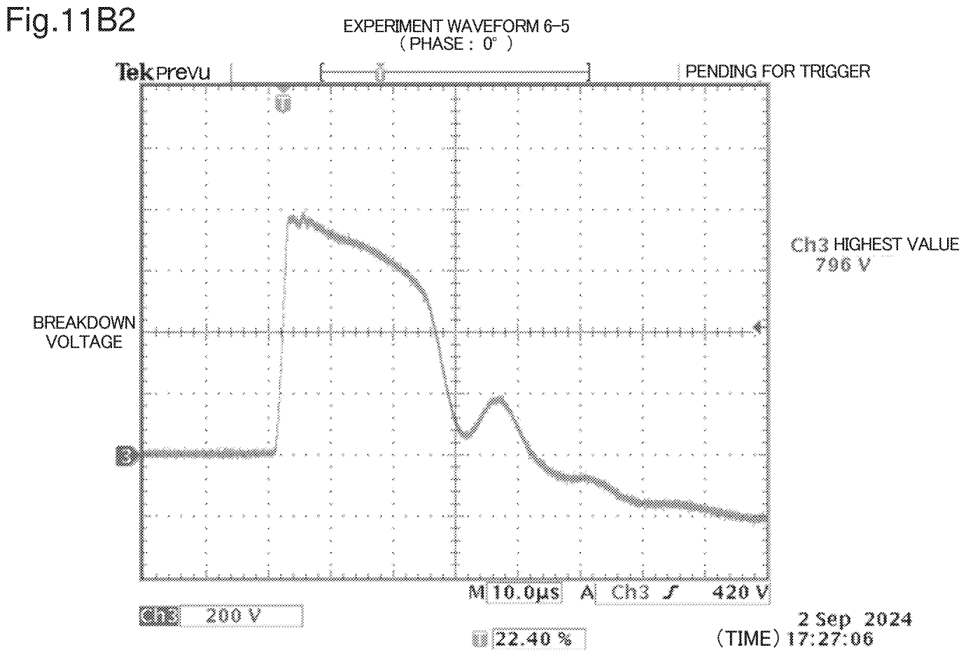

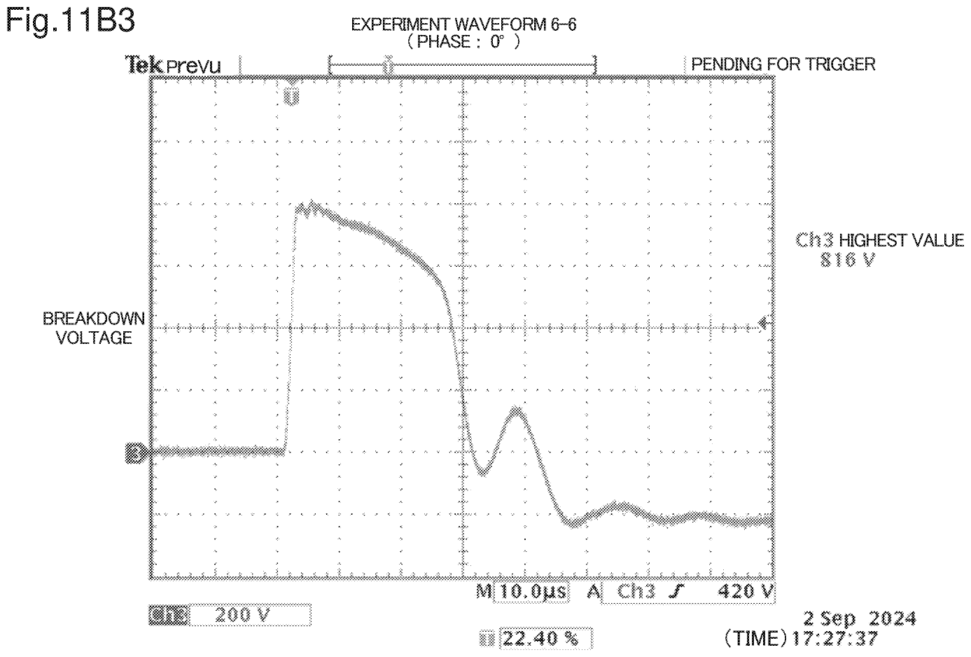

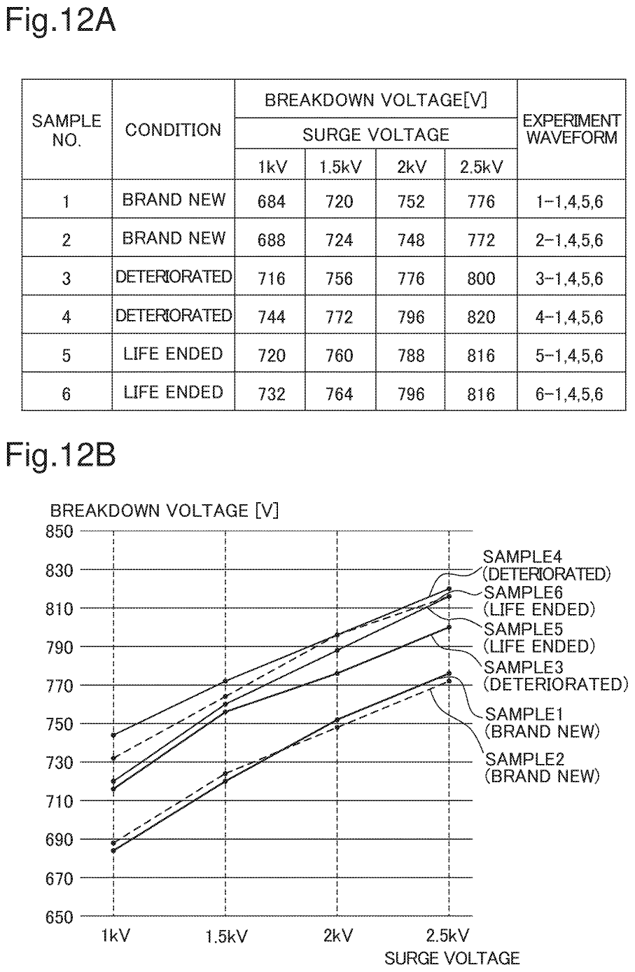

FIG. 9A1-9A3, FIG. 9B1-9B3, FIG. 10A1-10A3, FIG. 10B1-10B3, FIG. 11A1-11A3, and FIG. 11B1-11B3 respectively show graphs of the breakdown-voltage measurement results obtained through the surge tests (maximum surge voltages: 1.5 kV, 2 kV, and 2.5 kV, phase: 0°) for the corresponding one of samples 1, 2, 3, 4, 5, and 6. FIG. 12A and FIG. 12B indicate the breakdown voltages, according to the measurement results obtained through the surge test executed with the surge voltage of maximum 1 kV, 1.5 kV, 2 Kv, and 2.5 Kv (phase: 0°).

As shown in FIG. 8A, FIG. 8B, FIG. 12A, and FIG. 12B, the breakdown voltage of the varistor 22 is higher in the deteriorated products (samples 3 to 6, end of life inclusive), than in the brand new products (sample 1 and 2). For example, when the surge test is executed with the surge voltage of maximum 1 kV (phase: 0°), the range of the breakdown voltage of the brand new varistors 22 (samples 1 and 2) is 684 to 688V, while the range of the breakdown voltage of the deteriorated varistors 22 (samples 3 to 6, end of life inclusive) is 716 to 744V.

Through the surge test described above, findings have been obtained that the breakdown voltage of the varistor 22 is higher in the deteriorated products, than in the brand new products. Therefore, the operator can diagnose the deterioration of the varistor 22 from the breakdown voltage thereof, on the basis of such findings.

To be more specific, the operator decides whether the varistor 22 subjected to the deterioration diagnosis is usable, through comparison between the breakdown voltage of the varistor 22 subjected to the deterioration diagnosis, and a predetermined deterioration threshold TH. The deterioration threshold TH may be determined by calculating a boundary value, between the breakdown voltages measured in advance before and after deterioration, with respect to a varistor of the same quality as the varistor 22 to be subjected to the deterioration diagnosis, and adopting such boundary value as the deterioration threshold TH.

For example, the lowest value 716 V among the breakdown voltages of the deteriorated varistors 22, or 710 V which is lower than the lowest value 716V by a predetermined value, may be adopted in advance as the deterioration threshold TH, so that the operator may decide that, when the breakdown voltage of the varistor 22 subjected to the deterioration diagnosis is higher than the deterioration threshold TH, such varistor 22 is deteriorated and unusable. However, the setting of the deterioration threshold TH is not limited to the above.

Since the breakdown voltage of the varistor 22 can be visually recognized by the operator through the display device 13, setting the deterioration threshold TH in advance enables the breakdown voltage of the varistor 22 subjected to the deterioration diagnosis to be easily compared with the deterioration threshold TH.

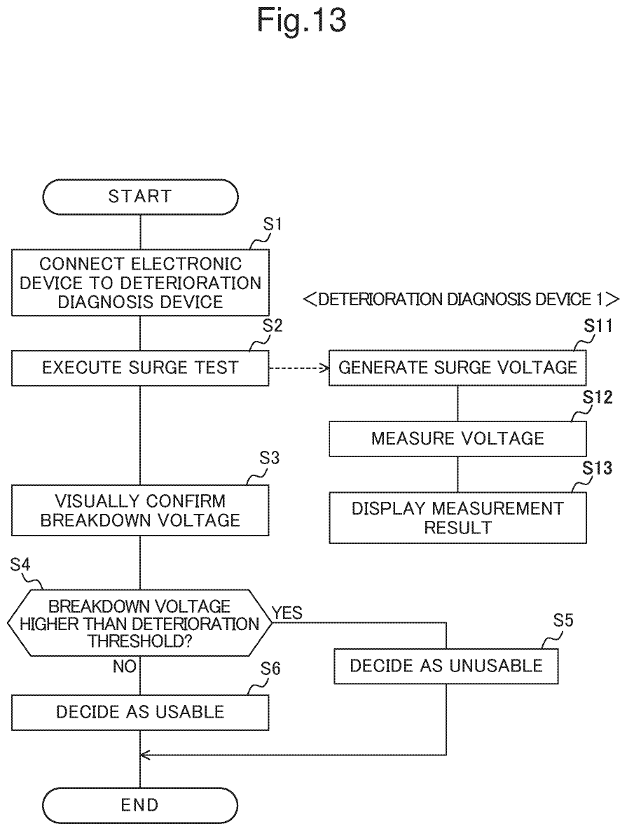

Referring now to a flowchart shown in FIG. 13, a deterioration diagnosis method, for diagnosing whether the varistor 22 in the electronic device 2 collected from the market is usable, will be described hereunder.

The operator connects the electronic device 2 collected from the market to the deterioration diagnosis device 1 (S1). To be more specific, the operator connects the power input terminal 23 of the electronic device 2, to the power output terminal 18 of the deterioration diagnosis device 1.

Then the operator instructs the deterioration diagnosis device 1 to execute the surge test (e.g., with surge voltage of maximum 1 kV, phase: 0°), through the operation device 12 (S2). The controller 110 causes the surge voltage generation device 15 to generate the surge voltage (S11), according to the instruction from the operator inputted through the operation device 12, causes the voltage measurement device 16 to measure the voltage (S12), and causes the display device 13 to display the breakdown voltage, representing the measurement result obtained by the voltage measurement device 16 (S13).

The operator confirms the breakdown voltage of the varistor 22 in the electronic device 2 (varistor subjected to the deterioration diagnosis) in view of the display device 13 (S3), and compares between the breakdown voltage and the deterioration threshold TH, thereby deciding whether the breakdown voltage is higher than the deterioration threshold TH (S4).

Upon deciding that the breakdown voltage is higher than the deterioration threshold TH (YES at S4), the operator decides that the varistor 22 is unusable (S5). In contrast, upon deciding that the breakdown voltage is not higher than the deterioration threshold TH (NO at S4), the operator decides that the varistor 22 is usable (S6).

This embodiment is based on the findings that the breakdown voltage of the varistor 22 is higher in the deteriorated product, than in the brand new product, and therefore proposing to decide whether the varistor 22 subjected to the deterioration diagnosis is usable, through the comparison between the breakdown voltage of the varistor 22 subjected to the deterioration diagnosis, and the deterioration threshold TH based on the breakdown voltage of the deteriorated varistor 22.

The arrangement according to the foregoing embodiment enables the breakdown voltage to be measured, without the need to remove the varistor 22 from the mother board, by applying the surge voltage to the varistor 22 in the electronic device 2, with the deterioration diagnosis device 1 from outside of the electronic device 2. Therefore, the deterioration diagnosis of the varistor 22 can be efficiently performed, with the varistor 22 kept mounted on the mother board, without the need to remove the varistor 22 therefrom.

The disclosure may be modified in various manners, without limitation to the foregoing embodiment. For example, according to the embodiment, the operator confirms the breakdown voltage of the varistor 22 in the electronic device 2 (varistor subjected to the deterioration diagnosis) in view of the display device 13 (S3), and compares between the breakdown voltage and the deterioration threshold TH, thereby deciding whether the breakdown voltage is higher than the deterioration threshold TH (S4). Instead, for example, the controller 110 of the deterioration diagnosis device 1 may store therein the deterioration threshold TH in advance, acquire, from the voltage measurement device 16, the breakdown voltage representing the measurement result obtained by the voltage measurement device 16, thereby deciding whether the breakdown voltage is higher than the deterioration threshold TH, and cause the display device 13 to display a message indicating the decision result.

The reuse of the electronic devices has come to be promoted recently, so that the electronic devices that have been used are collected, and the components therein in a good condition are recycled. Although the service life of the varistor is relatively long, when the varistor is subjected to the surge voltage higher than the rated voltage for an extended period of time, the varistor is deteriorated, or malfunctions. For such reason, the deterioration of the varistor has to be diagnosed.

When the varistor is deteriorated, the varistor voltage varies. The varistor voltage refers to the voltage generated when a direct current of 1 mA flows between the terminals of the varistor. Normally the deterioration diagnosis of the varistor is performed with a dedicated diagnosis device, after removing the varistor from the mother board to make the varistor alone, which is both troublesome and time-consuming. To improve the work efficiency, it is preferable to enable the deterioration diagnosis of the varistor to be performed with the varistor kept mounted on the mother board, without the need to remove the varistor therefrom.

Techniques to detect the deterioration of the varistor, but unlike the foregoing embodiment, have been known. Examples of such techniques include using a temperature fuse to detect the deterioration of the varistor, in order to prevent fuming or ignition due to thermal runaway arising from the deterioration of the varistor. However, there is an increasing demand for a more efficient method for diagnosing the deterioration of the varistor.

With the arrangement according to the foregoing embodiment, the deterioration diagnosis of the varistor can be efficiently executed, with the varistor kept mounted on the mother board, without the need to remove the varistor therefrom.

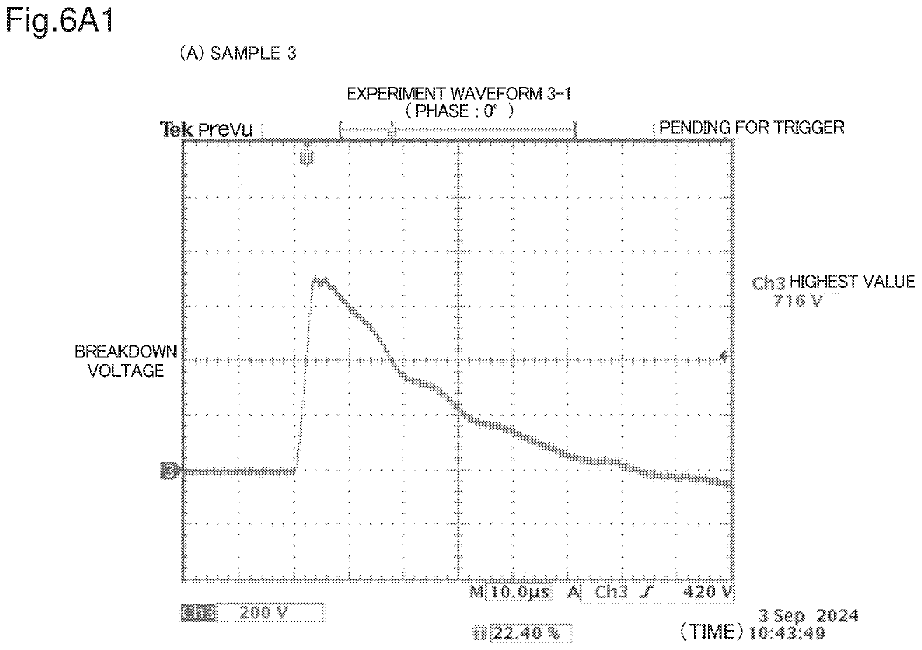

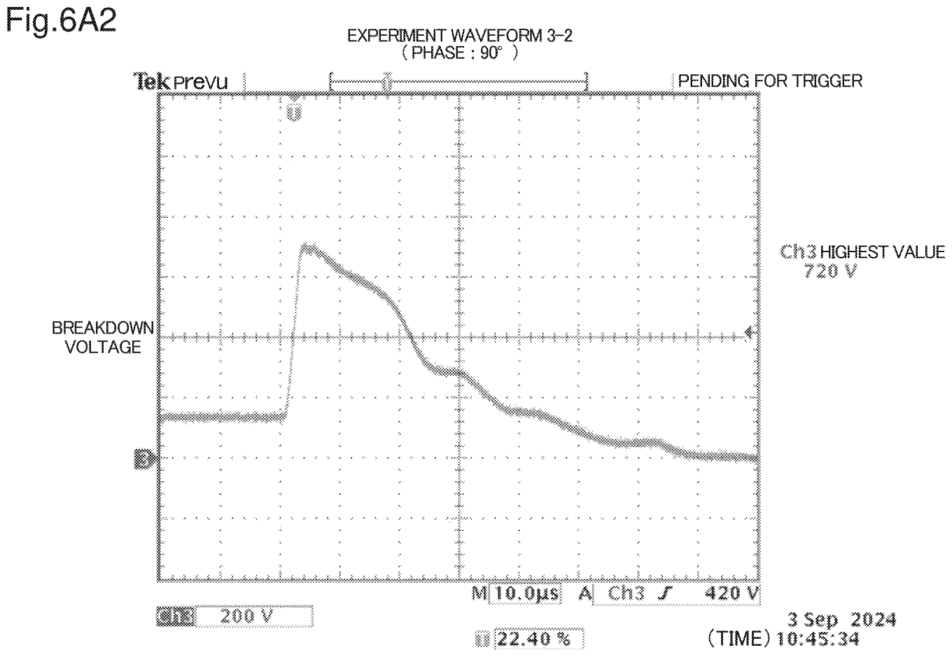

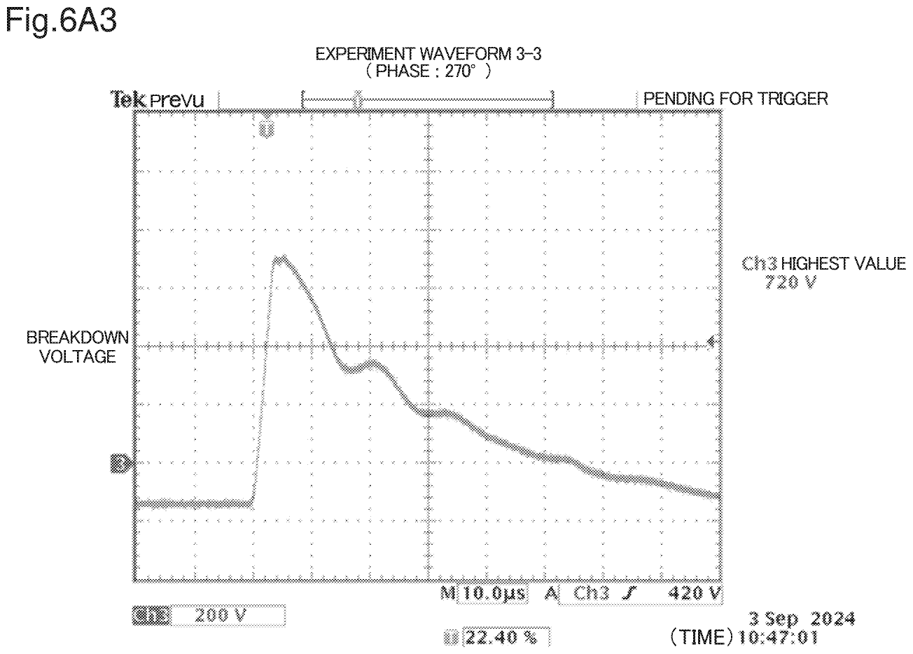

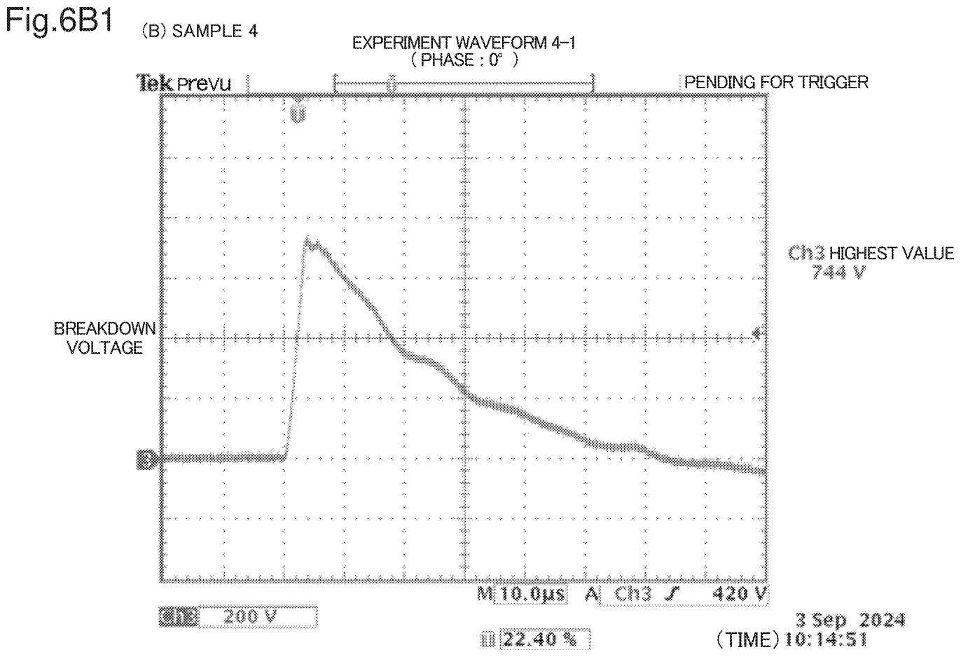

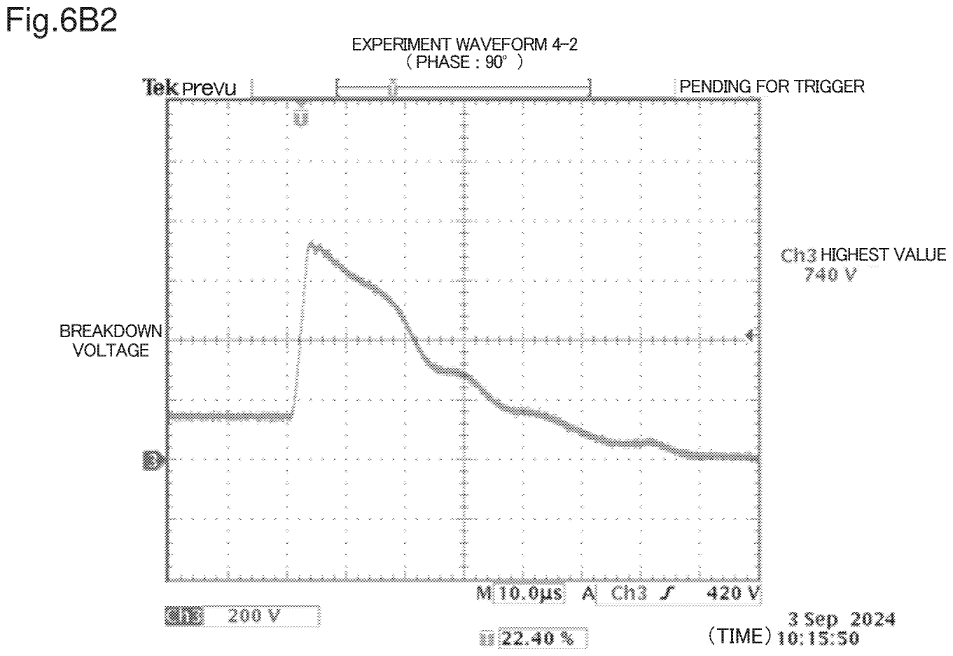

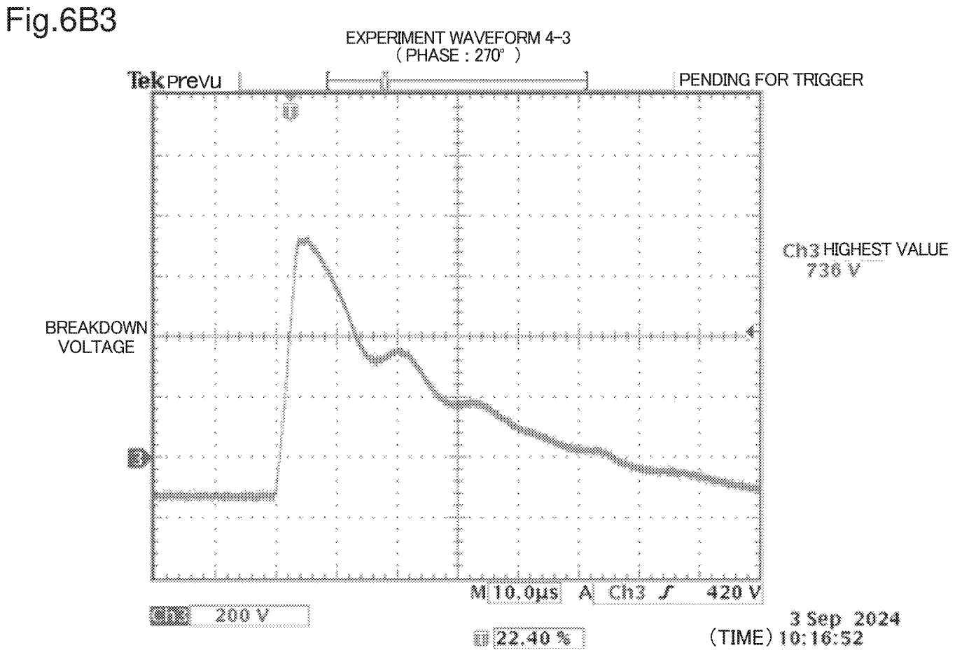

Further, the configurations and processings described in the embodiment with reference to FIG. 1 to FIG. 13 are merely exemplary, and in no way intended to limit the disclosure to those configurations and processings.

While the present disclosure has been described in detail with reference to the embodiments thereof, it would be apparent to those skilled in the art that various changes and modifications may be made therein within the scope defined by the appended claims.

What is claimed is;

1. A varistor deterioration diagnosis method, for diagnosing deterioration of the varistor, provided in an electronic device including a protected circuit to be protected from a surge, and the varistor connected to a power line between a commercial power source that supplies an AC voltage and the protected circuit, the deterioration diagnosis method comprising:
applying a predetermined surge voltage to the varistor provided in the electronic device;
measuring a breakdown voltage of the varistor; and
deciding that the varistor is unusable, when the measured breakdown voltage exceeds a predetermined deterioration threshold, and deciding that the varistor is usable, when the measured breakdown voltage is equal to or lower than the predetermined deterioration threshold.

2. The varistor deterioration diagnosis method according to claim 1,
wherein the deterioration threshold is determined by calculating a boundary value between the breakdown voltages, measured in advance before and after deterioration, with respect to a varistor of same quality as the varistor to be subjected to the deterioration diagnosis.

3. The varistor deterioration diagnosis method according to claim 1,
wherein whether the varistor is usable is decided by measuring the breakdown voltage, keeping the varistor in an on-board state without removing the varistor in the electronic device from a circuit board.

4. A varistor deterioration diagnosis device that diagnoses deterioration of the varistor, provided in an electronic device including a protected circuit to be protected from a surge, the varistor connected to a power line between a commercial power source that supplies an AC voltage and the protected circuit, and a power input terminal connected to the commercial power source, the varistor deterioration diagnosis device comprising:
a surge voltage generation device that generates a predetermined surge voltage, from an AC voltage of the commercial power source;
a power output terminal that is connected to the power input terminal of the electronic device, and supplies the surge voltage to the electronic device;
a voltage measurement device that measures a breakdown voltage of the varistor, applied to the power output terminal;
a display device; and
a controller that causes the display device to display the breakdown voltage measured by the voltage measurement device.

5. The varistor deterioration diagnosis device according to claim 4,
wherein the controller is configured to:
store therein in advance a predetermined deterioration threshold;
acquire, from the voltage measurement device, information indicating the breakdown voltage representing a measurement result obtained by the voltage measurement device;
decide whether the breakdown voltage is higher than the deterioration threshold; and
cause the display device to display a message indicating a decision result.

6. The varistor deterioration diagnosis device according to claim 5,
wherein the deterioration threshold is determined by calculating a boundary value between the breakdown voltages, measured in advance before and after deterioration, with respect to a varistor of same quality as the varistor to be subjected to the deterioration diagnosis.

7. The varistor deterioration diagnosis device according to claim 4,
wherein the voltage measurement device extracts a peak value of a voltage waveform applied to the power output terminal, and outputs the peak value as the breakdown voltage.
